(19) United States
(12) Patent Application Publication
(10) Pub. No.: US 2023/0354654 A1
(43) Pub. Date: Nov. 2, 2023

(54) DISPLAY PANEL, DISPLAY APPARATUS, AND METHOD FOR PREPARING DISPLAY APPARATUS

(71) Applicant: KunShan Go-Visionox Opto-Electronics Co., Ltd, Kunshan (CN)

(72) Inventors: Fa-Hsyang CHEN, Kunshan (CN); Cuili GAI, Kunshan (CN); Yinghai MA, Kunshan (CN); Zidong GUO, Kunshan (CN); Xuyang ZHANG, Kunshan (CN); Junfeng LI, Kunshan (CN)

(73) Assignee: KunShan Go-Visionox Opto-Electronics Co., Ltd, Kunshan (CN)

(21) Appl. No.: 18/343,112

(22) Filed: Jun. 28, 2023

Related U.S. Application Data
(63) Continuation of application No. PCT/CN2021/137177, filed on Dec. 10, 2021.

(30) Foreign Application Priority Data
Jun. 9, 2021 (CN) 202110644626.6

(51) Int. Cl. H10K 59/126; H10K 59/12

(52) U.S. Cl. CPC H10K 59/126; H10K 59/1201

(57) ABSTRACT

A display panel, a display apparatus and a method for preparing the display apparatus. The display panel includes: a fingerprint recognition region; a display region arranged as at least partially surrounding the fingerprint recognition region; an active layer arranged on a side of the substrate and comprising a plurality of active units distributed in an array on the substrate; and a light blocking layer arranged on a side of the active layer facing the substrate and arranged in the fingerprint recognition region. The light blocking layer includes a plurality of light blocking units, and along a direction perpendicular to the display panel, orthographic projections of the plurality of light blocking units on the substrate cover orthographic projections of the plurality of active units on the substrate.

### CROSS-REFERENCE TO RELATED APPLICATIONS

The present application is a continuation of International Application No. PCT/CN2021/137177 filed on Dec. 10, 2021, which claims the benefit of priority to Chinese Patent Application No. 202110644626.6 filed on Jun. 9, 2021, and entitled “ARRAY SUBSTRATE AND METHOD FOR PREPARING DISPLAY APPARATUS”, both of which are hereby incorporated by reference in their entireties.

### TECHNICAL FIELD

The present application relates to the technical field of electronic products, and particularly, to a display panel, a display apparatus and a method for preparing the display apparatus.

### BACKGROUND

With user requirements becoming higher and higher, multiple functions including an under-screen camera and fingerprint recognition are integrated in a display apparatus. Preparing the display apparatus generally includes process flows including preparing an array substrate and bonding a circuit board. In a process of bonding the circuit board to the array substrate, it is necessary to firstly remove a tape used for blocking a fingerprint recognition region, and then align the circuit board with the array substrate by using an alignment light source so as to achieve the bonding of the circuit board to the array substrate. However, in the process of performing the alignment by using the alignment light source, transistors in the fingerprint recognition region are exposed to light, which causes a deviation in characteristics of the transistors, resulting in an uneven display brightness in the fingerprint recognition region, thereby leading to a display apparatus with different display effects.

Therefore, there is an urgent need for a display panel, a display apparatus, and a method for preparing the display apparatus.

### SUMMARY

Embodiments of the present application provide a display panel, a display apparatus and a method for preparing the display apparatus. Light blocking units are arranged to block a strong light source entering a fingerprint recognition region, so as to prevent a change in characteristics of active units which is caused by the strong light source entering the active units in the fingerprint recognition region in a process of bonding a circuit board, thereby improving display uniformity of the display panel.

In a first aspect, the embodiments of the present application provide a display panel including: a fingerprint recognition region; a display region arranged as at least partially surrounding the fingerprint recognition region; an active layer arranged on a side of the substrate and comprising a plurality of active units distributed in an array on the substrate; and a light blocking layer arranged on a side of the active layer facing the substrate and arranged in the fingerprint recognition region, wherein the light blocking layer includes a plurality of light blocking units, and along a direction perpendicular to the display panel, orthographic projections of the plurality of light blocking units on the substrate cover orthographic projections of the plurality of active units on the substrate.

In a second aspect, the embodiments of the present application provide a display apparatus including the display panel described above and a fingerprint recognition element corresponding to the fingerprint recognition region arranged in the display panel.

In a third aspect, the embodiments of the present application provide a method for preparing the display apparatus, and the method includes: providing a substrate; forming a plurality of light blocking units on the substrate to form a patterned light blocking layer; and forming a plurality of active units on a side of the light blocking layer away from the substrate to form an active layer, wherein orthographic projections of the plurality of light blocking units on the substrate cover orthographic projections of the plurality of active units on the substrate.

The display panel according to the embodiments of the present application includes the substrate, the active layer, and the light blocking layer. The light blocking layer is arranged on a side of the active layer facing the substrate and arranged in the fingerprint recognition region. The light blocking layer includes the plurality of light blocking units, the orthographic projections of the light blocking units on the substrate cover the orthographic projections of the active units on the substrate, and the orthographic projections of the plurality of light blocking units at least cover orthographic projections of a part of the plurality of active units, that is, the light blocking units and the active units are arranged in a one-to-one correspondence, or one light blocking unit may block the plurality of active units meanwhile. The light blocking unit is used in a process of bonding the circuit board to the display panel to block external light from a side of the substrate (away from the active layer) corresponding to the fingerprint recognition region, so as to prevent a change in characteristics of the active units which is caused by the strong light source entering the active units positioned on the active layer in the fingerprint recognition region, which otherwise affects display uniformity of the display panel.

### BRIEF DESCRIPTION OF THE DRAWINGS

FIG. 1 is a top view of a display panel according to an embodiment of the present application.

FIG. 2 is a cross-sectional view of the display panel in FIG. 1 along the C-C direction.

FIG. 3 is a cross-sectional view of a display panel in another embodiment.

FIG. 4 is a cross-sectional view of a display panel in yet another embodiment.

FIG. 5 is a flow chart of a method for preparing a display apparatus according to one embodiment of the present application.

FIG. 6 to FIG. 9 are schematic views of a display panel in a preparing process according to the present application.

### DETAILED DESCRIPTION

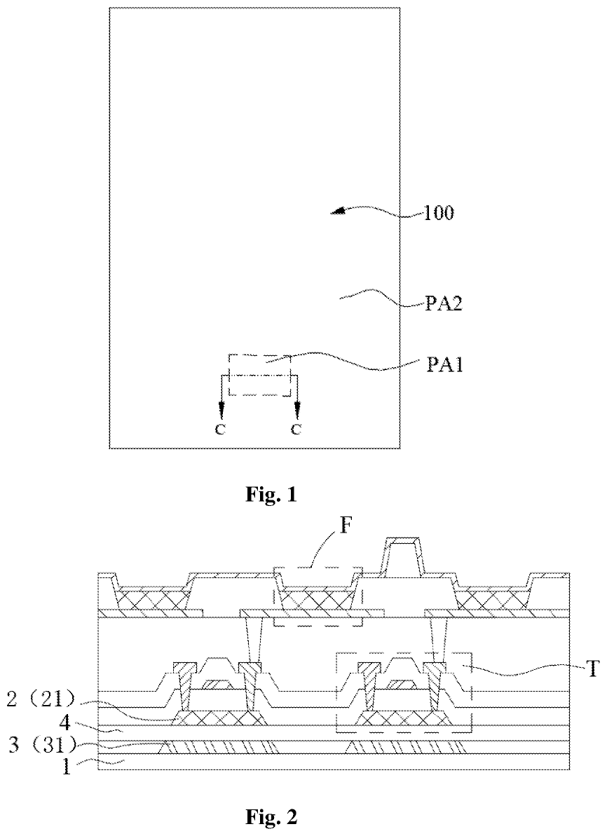

For a better understanding of the present application, a display panel and a method for preparing a display apparatus according to embodiments of the present application will be described in detail below with reference to FIG. 1 to FIG. 9.

With reference to FIG. 1 to FIG. 4, embodiments of the present application provide a display panel 100 including a substrate 1, an active layer 2 arranged on a side of the substrate 1, and a light blocking layer 3. The display panel 100 includes a fingerprint recognition region PA1 and a display region PA2 arranged as at least partially surrounding the fingerprint recognition region PA1, and the active layer 2 includes a plurality of active units 21 distributed in an array on the substrate 1. The light blocking layer 3 is arranged on a side of the active layer 2 facing the substrate 1 and arranged in the fingerprint recognition region PM. The light blocking layer 3 includes a plurality of light blocking units 31, and along a direction perpendicular to the display panel, orthographic projections of the plurality of light blocking units 31 on the substrate 1 cover orthographic projections of the plurality of active units 21 on the substrate 1.

The fingerprint recognition region PA1 in the display panel 100A and a fingerprint recognition element are arranged correspondingly. Affected by a process order, under a condition that a process flow of bonding a circuit board to the display panel 100 is performed, a light blocking tape blocking corresponding active units 21 in the fingerprint recognition region PA1 in the display panel is required to be removed in a process of bending and bonding a flexible circuit board. Then, under a condition that the bonding and the alignment are performed by using an alignment light source, the blocking tape cannot block alignment light and ambient light, so that the alignment light source may directly enter the active units 21 positioned in the fingerprint recognition region PA1, which causes a change in characteristics of the active units 21, thereby affecting a normal operation of the display panel 100, and finally causing the display panel to have different display effects. Accordingly, in order to prevent the alignment light source from directly entering the active units 21 positioned in the fingerprint recognition region PA1 in the bonding process, in the present application, the light blocking layer 3 corresponding to the fingerprint recognition region PA1 is arranged between the substrate 1 and the active layer 2, and the active units 21 are blocked by the light blocking units 31 on the light blocking layer 3 to absorb and block the light and prevent the light source from entering the active units 21, thereby preventing the change in the characteristics of the active units 21 so as to ensure display uniformity of the display panel 100.

With reference to FIG. 2, the plurality of active units 21 and the plurality of light blocking units 31 are arranged in a one-to-one correspondence. Along a direction perpendicular to the display panel 100, an orthographic projection of one of the light blocking units 31 on the substrate 1 covers an orthographic projection of only one of the active units 21 on the substrate 1, so as to prevent the light blocking units 31 form covering a region of the display panel 100 where the active units 21 are not arranged, so that the part of the light blocking units 31 cannot block the active units 21, and therefore the light blocking units 31 are used more effectively.

With reference to FIG. 4, along the direction perpendicular to the display panel 100, a same light blocking unit 31 covers at least two adjacent active units 21, so that an orthographic projection of one light blocking unit 31 on the substrate 1 covers orthographic projections of at least two active units 21 on the substrate 1, thereby effectively reducing a number of light blocking units 31 required and facilitating a preparation of the light blocking units 31.

The display panel 100 further includes a pixel circuit, and a position in the pixel circuit where a plurality of transistors are arranged is adjusted according to practical requirements. Under a condition that intervals between the transistors are relatively great, the light blocking units 31 are arranged according to the above one-to-one correspondence, so that one active unit 21 is blocked by one light blocking unit 31. Under a condition that intervals between the plurality of transistors are relatively small, one light blocking unit 31 blocks at least two active units 21. In a practical preparing process, the number of the light blocking units 31 and a position where the light blocking units 31 are arranged may be adjusted according to an arrangement structure of the active unit 21 of each transistor in the pixel circuit, which is not specifically limited here.

An orthographic projection of each of the light blocking units 31 on the substrate 1 is at least one of a polygon, a circle, an oval, and a belt in shape. Since the light blocking units 31 are arranged to block the light entering the active unit 21 of the transistor, a shape and a size of the light blocking unit 31 may be set according to a shape and a size of the active unit 21 of each transistor in the pixel circuit to achieve a better light blocking effect.

In the embodiment, the pixel circuit is a 7T1C circuit, that is, the pixel circuit includes seven transistors and one capacitor C. The orthographic projections of the light blocking units 31 on the substrate 1 cover orthographic projections of the active units 21 of the seven transistors in the pixel circuit on the substrate 1. A same light blocking unit 31 may block the active unit 21 of only one transistor in the pixel circuit, that is, seven light blocking units are arranged to respectively block the active units 21 of seven transistors in the pixel circuit, so as to improve the light blocking effect of the pixel circuit and improve a light blocking efficiency of the light blocking units 31.

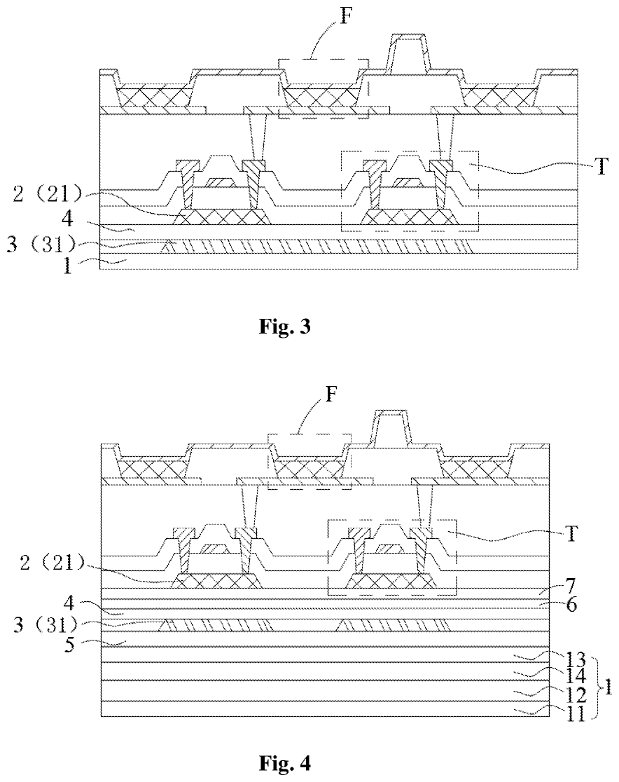

With reference to FIG. 2 and FIG. 3, in order to reduce a reflectivity of the light blocking layer 3 with respect to light emitted from a light-emitting layer F of the display panel 100, the display panel 100 further includes a first inorganic layer 4 arranged on a side of the light blocking layer 3 away form the substrate 1, and the first inorganic layer 4 includes at least one of silicon oxide and silicon nitride.

It is understood that the first inorganic layer 4 is arranged between the light-emitting layer F of the display panel 100 and the light blocking layer 3, and by selecting a material of the first inorganic layer 4, adjusting a thickness of the first inorganic layer 4, and changing a film layer structure of an upper layer of the light blocking layer 3, the reflectivity of the light blocking layer 3 with respect to the light from the light-emitting layer F can be effectively reduced. By adding the first inorganic layer 4, a negative effect caused by enhanced reflective light of the light blocking layer 3 from the upper light-emitting layer F of the display panel may be reduced. The first inorganic layer 4 is made of inorganic materials such as silicon oxide, silicon nitride and silicon oxynitride, and has a thickness ranging from 100 nm to 500 nm. In the embodiment, the first inorganic layer 4 is silicon oxide having a thickness of 380 mm. Further, the first inorganic layer 4 may be a single layer or a plurality of layers, and specifically may include at least one of a silicon oxide layer and a silicon nitride layer.

With reference FIG. 4, the substrate 1 includes a first substrate 11, a second inorganic layer 12 and a second substrate 13 that are stacked, the light blocking layer 3 and the first inorganic layer 4 are stacked on the second substrate 13, and along a stacking direction, a thickness of the second inorganic layer 12 is less than or equal to a thickness of the first inorganic layer 4.

It should be noted that, according to practical simulation experiments, under a condition that the thickness of the second inorganic layer 12 is less than or equal to the thickness of the first inorganic layer 4, a light transmittance of the light blocking layer 3 with respect to external light from a side of the substrate 1 away from the light blocking layer 3 and the reflectivity of the light blocking layer 3 with respect to the light emitted from the light-emitting layer F of the display panel can be effectively reduced. The second inorganic layer 12 is mainly used for isolating water and oxygen from the outside, and preventing water and oxygen from entering, through the substrate 1, components (such as the transistors of the display panel 100) which are easily corroded, which otherwise affects a lifespan of the display panel.

With reference to FIG. 4, an amorphous silicon layer 14 is arranged between the second substrate 13 and the second inorganic layer 12. The first substrate 11 and the second substrate 13 may specifically be made of a flexible PI (PolyimideFilm) material, and may have a same thickness, thereby facilitating the forming and reducing production costs. Of course, the first substrate 11 and the second substrate 13 may have different thicknesses, for example, a thickness of the second substrate 13 is less than a thickness of the first substrate 11, or a thickness of the second substrate 13 is greater than a thickness of the first substrate 11, which is not limited specifically. Meanwhile, a double-layer substrate may be arranged, so that a water and oxygen blocking effect of the substrate 1 can be effectively improved. Optionally, the second inorganic layer 12 has a thickness ranging from 100 nm to 1000 nm.

Optionally, a third inorganic layer 5 is arranged between the second substrate 13 and the light blocking layer 3, and the third inorganic layer 5 has a thickness ranging 100 nm to 1000 nm, which may be specifically adjusted according to performance requirements of the display panel for factors including optical performance, water and oxygen blocking.

Specifically, according to results of the practical simulation experiments, a film layer structure is obtained under a condition that thicknesses of the third inorganic layer 5, the first inorganic layer 4 and the second inorganic layer 12 increases in sequence, so that the light transmittance of the light blocking layer 3 with respect to external light from a side of the substrate 1 away from the light blocking layer 3 and the reflectivity of the light blocking layer 3 with respect to the light emitted from the light-emitting layer F of the display panel can be further reduced.

Optionally, a fourth inorganic layer 6 and a fifth inorganic layer 7 are stacked in sequence on a side of the first inorganic layer 4 away from the light blocking layer 3, and the fourth inorganic layer 6 covers the first inorganic layer 4. Specifically, the fourth inorganic layer 6 is made of a silicon nitride layer, and the fifth inorganic layer 7 is made of a silicon oxide layer.

In order to improve an absorption effect of the light blocking layer 3 on the light to block more light, in some optional embodiments, along a stacking direction of film layers of the display panel 100, the light blocking layer 3 has a thickness ranging from 10 nm to 100 nm, and the light blocking layer 3 includes a material layer with an ultraviolet light transmittance equal to or less than 1%.

It should be noted that since a material of the active units 21 on the active layer 2 is more sensitive to incoming ultraviolet light and has an easily changing electrical property, the light blocking layer 3 is required to be made of a material with a relatively low transmittance for the ultraviolet light. Specifically, the light blocking layer 3 may be made of an amorphous silicon material, because the amorphous silicon has a low transmittance for light having a wavelength of 100 nm or less, and can satisfy the requirements. In addition, since a maximum withstanding temperature of the display panel in the preparing process is 450° C., the material of the light blocking layer 3 is also required to satisfy a requirement of the withstanding temperature of 450° C.

Another embodiment of the present application also provides a display apparatus including the display panel and the fingerprint recognition element, the display panel is the display panel 100 according to any of the above embodiments, and the fingerprint recognition region PA1 in the display panel and the fingerprint recognition element is arranged correspondingly. The display apparatus has the technical effects of the technical solution of the display panel in any of the above embodiments, which will not be repeated here.

The display apparatus according to the embodiment of the present application may be a mobile phone, and may also be any electronic product with a display function, including but not limited to the following categories: televisions, notebook computers, desktop displays, tablet computers, digital cameras, smart bracelets, smart glasses, vehicle-mounted displays, medical equipment, industrial control equipment, touch interactive terminals, and the like, which are not particularly limited in the embodiment of the present application.

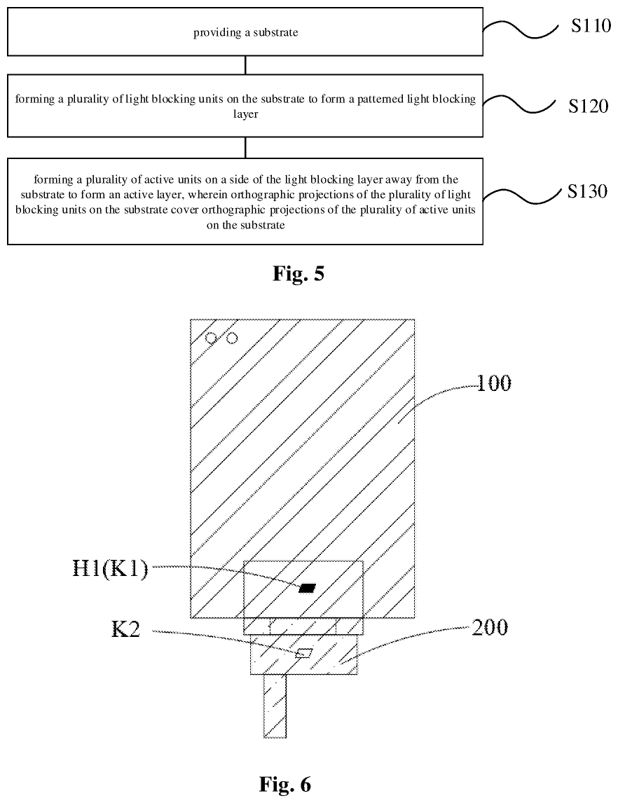

With reference to FIG. 5 to FIG. 9, a method for preparing the display apparatus according to the embodiments of the present application includes:

S110: providing the substrate 1;

S120: forming the plurality of light blocking units 31 on the substrate 1 to form a patterned light blocking layer 3;

S130: forming the plurality of active units 21 on the side of the light blocking layer 3 away from the substrate 1 to form the active layer 2, wherein the orthographic projections of the plurality of light blocking units 31 on the substrate 1 cover the orthographic projections of the plurality of active units 21 on the substrate 1.

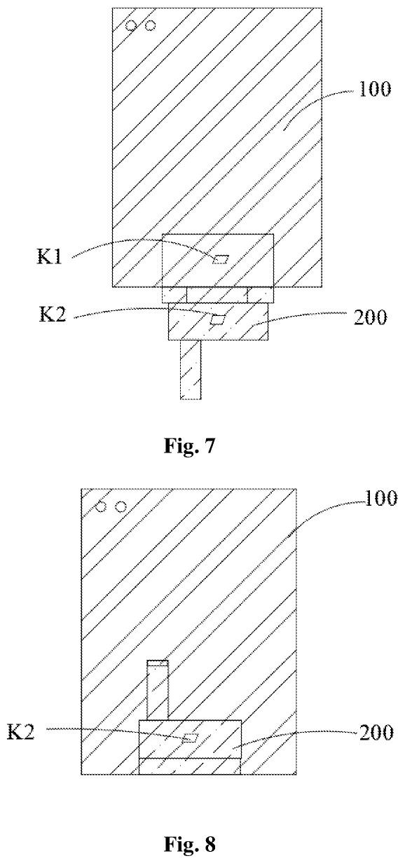

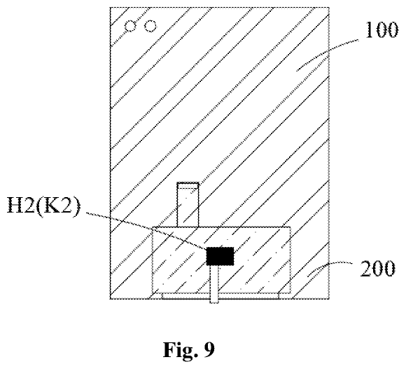

In the method, the light blocking layer 3 corresponding to the active units 21 is arranged between the substrate 1 and the active layer 2, and the active units 21 are blocked by the light blocking units 31 on the light blocking layer 3 to absorb and block the light and prevent the light source from entering the active units 21, thereby preventing the change in the characteristics of the active units 21 so as to ensure the display uniformity of the display panel 100. The method further includes: forming the light-emitting layer F and an encapsulation layer in sequence on a side of the active layer 2 away from the substrate 1 to form the display panel 100, and dividing the display panel 100 into the fingerprint recognition region and the display region arranged as at least partially surrounding the fingerprint recognition region;
arranging, on a side of the display panel 100 away from the substrate 1, a first groove K1 corresponding to the fingerprint recognition region, and the first groove K1 is covered with a first light blocking tape H1, as shown in FIG. 6;
peeling off the first light blocking tape H1 covering on the first groove K1, as shown in FIG. 7;
bonding a flexible circuit board 200 to the display panel 100, and the flexible circuit board 200 has a second groove K2 corresponding to the first groove K1, as shown in FIG. 8;
arranging the fingerprint recognition element in the first groove K1 and the second groove K2; and
covering a side of the second groove K2 away from the fingerprint recognition element with a second light blocking tape H2, as shown in FIG. 9.

The light blocking layer 3 with the plurality of light blocking units 31 are arranged to block the active units 21 positioned in the fingerprint recognition region, so as to prevent, in a process flow between peeling off the first light blocking tape H1 covering on the first groove K1 and covering a side of the second groove K2 away from the fingerprint recognition element with a second light blocking tape H2, the change in the characteristics of the active units 21 caused by the alignment light source or external ambient light entering the active units 21 under a condition that the flexible circuit board 200 is bonded to the display panel 100, which otherwise affects the display effect of the display apparatus.

It should be noted that the first light blocking tape H1 and the fingerprint recognition region are arranged correspondingly to block the active units 21 in the fingerprint recognition region; however, since the flexible circuit board 200 is required to be bonded to the display panel 100, and the fingerprint recognition element is arranged in the first groove K1 and the second groove K2, the first light blocking tape H1 on the first groove K1 is required to be peeled off firstly, so that the fingerprint recognition element is arranged in the first groove K1 and the second groove K2. In a process after the first light blocking tape H1 is peeled off and the second light blocking tape H2 is not arranged, the alignment light source or the external ambient light enters the active layer 2 through the first groove K1 and the second groove K2, therefore, in the embodiments according to the present application, the light blocking layer 3 is arranged correspondingly in the fingerprint recognition region, so as to effectively prevent, in a process flow of bonding the flexible circuit board 200, the alignment light source or the external ambient light from entering the active units 21, thereby improving the yield of the display apparatus.

In some optional embodiments, between forming the patterned light blocking layer 3 in the fingerprint recognition region and forming the active layer 2 on a side of the light blocking layer 3 away from the substrate 1, the method further includes: forming, on a side of the light blocking layer 3 away from the substrate 1, the first inorganic layer 4. The first inorganic layer 4 is arranged between the light-emitting layer F of the display apparatus and the light blocking layer 3, and by selecting a material of the first inorganic layer 4, adjusting a thickness of the first inorganic layer 4, and changing a film layer structure of an upper layer of the light blocking layer 3, the reflectivity of the light blocking layer 3 with respect to the light from the light-emitting layer F can be effectively reduced.

What is claimed is:

1. A display panel, comprising:
a fingerprint recognition region;
a display region arranged as at least partially surrounding the fingerprint recognition region;
a substrate arranged in the fingerprint recognition region and the display region;
an active layer arranged on a side of the substrate and comprising a plurality of active units distributed in an array on the substrate; and
a light blocking layer arranged on a side of the active layer facing the substrate and arranged in the fingerprint recognition region, wherein the light blocking layer comprises a plurality of light blocking units, and along a direction perpendicular to the display panel, orthographic projections of the plurality of light blocking units on the substrate cover orthographic projections of the plurality of active units on the substrate.

2. The display panel according to claim 1, wherein the plurality of light blocking units and the plurality of active units are arranged in a one-to-one correspondence, and an orthographic projection of one of the light blocking units on the substrate covers an orthographic projection of only one of the active units on the substrate.

3. The display panel according to claim 1, wherein along the direction perpendicular to the display panel, an orthographic projection of one of the light blocking units on the substrate covers orthographic projections of at least two adjacent active units on the substrate.

4. The display panel according to claim 1, further comprising a first inorganic layer arranged between the light blocking layer and the active layer, wherein the first inorganic layer comprises at least one of silicon oxide and silicon nitride.

5. The display panel according to claim 4, wherein the substrate comprises a first substrate, a second inorganic layer and a second substrate that are stacked, the light blocking layer and the first inorganic layer are stacked on a side of the second substrate away from the first substrate, and a thickness of the second inorganic layer is less than or equal to a thickness of the first inorganic layer.

6. The display panel according to claim 5, further comprising a third inorganic layer arranged between the second substrate and the light blocking layer, wherein along a stacking direction of film layers of the display panel, the first inorganic layer has a thickness ranging from 100 nm to 500 nm, the second inorganic layer has a thickness ranging from 100 nm to 1000 nm, and the third inorganic layer has a thickness ranging 100 nm to 1000 nm.

7. The display panel according to claim 6, wherein along the stacking direction, thicknesses of the third inorganic layer, the first inorganic layer, and the second inorganic layer increase in sequence.

8. The display panel according to claim 5, wherein an amorphous silicon layer is arranged between the second substrate and the second inorganic layer.

9. The display panel according to claim 5, wherein a fourth inorganic layer and a fifth inorganic layer are stacked in sequence on a side of the first inorganic layer away from the light blocking layer, and the fourth inorganic layer covers the first inorganic layer.

10. The display panel according to claim 1, wherein the light blocking layer has a thickness ranging from 10 nm to 100 nm, and the light blocking layer comprises a material layer with an ultraviolet light transmittance equal to or less than 1%.

11. The display panel according to claim 10, wherein the light blocking layer is made of amorphous silicon.

12. The display panel according to claim 1, wherein an orthographic projection of each of the light blocking units on the substrate is at least one of a polygon, a circle, an oval, and a belt in shape.

13. The display panel according to claim 1, wherein the display panel further comprises a pixel circuit, and the pixel circuit comprises seven transistors and one capacitor, wherein an orthographic projection of one of the light blocking units on the substrate at least covers an orthographic projection of an active unit of one transistor of the pixel circuit on the substrate.

14. The display panel according to claim 13, wherein along the direction perpendicular to the display panel, an orthographic projection of one of the light blocking units on the substrate covers an orthographic projection of only one of the active units on the substrate;
or along the direction perpendicular to the display panel, an orthographic projection of one of the light blocking units on the substrate covers orthographic projections of active units of at least two transistors on the substrate.

15. A display apparatus comprising the display panel according to claim 1 and a fingerprint recognition element corresponding to the fingerprint recognition region arranged in the display panel.

16. A method for preparing the display apparatus according to claim 15, comprising:
providing a substrate;
forming a plurality of light blocking units on the substrate to form a patterned light blocking layer; and
forming a plurality of active units on a side of the light blocking layer away from the substrate to form an active layer, wherein orthographic projections of the plurality of light blocking units on the substrate cover orthographic projections of the plurality of active units on the substrate.

17. The method according to claim 16, further comprising:
forming a light-emitting layer and an encapsulation layer in sequence on a side of the active layer away from the substrate to form a display panel, and dividing the display panel into a fingerprint recognition region and a display region, wherein the display region is arranged as at least partially surrounding the fingerprint recognition region;
arranging, on a side of the display panel away from the substrate, a first groove corresponding to the fingerprint recognition region, the first groove being covered with a first light blocking tape;
peeling off the first light blocking tape covering on the first groove;
bonding a flexible circuit board to the display panel, wherein the flexible circuit board has a second groove corresponding to the first groove;
arranging the fingerprint recognition element in the first groove and the second groove; and
covering a side of the second groove away from the fingerprint recognition element with a second light blocking tape.

18. The method according to claim 17, wherein between forming the plurality of light blocking units on the substrate to form the patterned light blocking layer and forming the plurality of active units on a side of the light blocking layer away from the substrate to form the active layer, the method further comprises:
forming, on a side of the light blocking layer away from the substrate, a first inorganic layer.
